(19) United States
(12) Patent Application Publication
(10) Pub. No.: US 2011/0056812 A1
(43) Pub. Date: Mar. 10, 2011

(54) NANO-ELECTRO-MECHANICAL SWITCHES USING THREE-DIMENSIONAL SIDEWALL-CONDUCTIVE CARBON NANOFIBERS AND METHOD FOR MAKING THE SAME

(76) Inventors: Anupama B. KAUL, Arcadia, CA (US); Abdur R. Khan, La Crescenta, CA (US)

(21) Appl. No.: 12/849,784

(22) Filed: Aug. 3, 2010

Related U.S. Application Data
(60) Provisional application No. 61/240,602, filed on Sep. 8, 2009.

(51) Int. Cl. H01H 57/00; B05D 5/12; B32B 1/00; C23C 14/35

(52) U.S. Cl. 200/181; 427/113; 428/367; 204/192.15; 977/788

(57) ABSTRACT

The present disclosure describes a method for fabricating three-dimensional sidewall-conductive carbon nanofibers (CNFs) on selective substrates. In particular, fabrication of three-dimensional sidewall-conductive CNFs on niobium titanium nitride (NbTiN) layer is described. The present disclosure also describes a nano-electro-mechanical switch using one or more three-dimensional sidewall-conductive CNFs.

### CROSS REFERENCE TO RELATED APPLICATIONS

The present application claims priority to U.S. Provisional Application No. 61/240,602, filed on Sep. 8, 2009, which is incorporated herein by reference in its entirety.

### STATEMENT OF GOVERNMENT GRANT

The invention described herein was made in the performance of work under a NASA contract, and is subject to the provisions of Public Law 96-517 (35 U.S.C.§202) in which the Contractor has elected to retain title.

### FIELD

The present disclosure relates to nano-scale devices and related methods of fabrication and/or use. More particularly, this disclosure relates to nano-electro-mechanical switches using three-dimensional sidewall-conductive carbon nanofibers and to a method for fabricating three-dimensional sidewall-conductive carbon nanofibers on selective substrates.

### SUMMARY

According to a first aspect of the present disclosure, a method for fabricating sidewall-conductive carbon nanofibers (CNFs) is provided, said method comprising depositing a niobium titanium nitride (NbTiN) layer on a substrate; depositing a catalyst layer on the NbTiN layer; patterning the catalyst layer; and growing at least one sidewall-conductive CNF on the patterned catalyst layer.

According to a second aspect of the present disclosure, a nano-electro-mechanical switch is provided, said nano-electro-mechanical switch comprising: a first electrical conductor; and a second electrical conductor located at a distance to the first electrical conductor, wherein at least one of the first electrical conductor and the second electrical conductor comprises a sidewall-conductive carbon nanofiber (CNF); and the first and the second electrical conductors are adapted to form a current conducting path when a voltage higher than a turn-on voltage is applied between the first and the second electrical conductors.

According to a third aspect of the present disclosure, a carbon nanofiber comprising electrically conductive sidewalls is provided.

According to a fourth aspect of the present disclosure, a method for fabricating three-dimensional carbon nanofibers (CNFs) with conformal dielectric sidewall coating is provided, said method comprising: depositing a nickel (Ni) catalyst layer on a silicon (Si) layer; patterning the Ni catalyst layer; and growing at least one three-dimensional CNF with conformal dielectric sidewall coating on the patterned Ni catalyst layer through direct current plasma enhanced chemical vapor deposition (dc PECVD).

### BRIEF DESCRIPTION OF DRAWINGS

The accompanying drawings, which are incorporated into and constitute a part of this specification, illustrate one or more embodiments of the present disclosure and, together with the description of example embodiments, serve to explain the principles and implementations of the disclosure.

FIG. 1 depicts a process flow for fabricating at least one three-dimensional sidewall-conductive carbon nanofibers (CNFs).

FIG. 2A depicts a current-voltage (I-V) curve of a sidewall-conductive CNF.

FIG. 2B depicts a CNF current-voltage measurement setup.

FIG. 3 shows current-voltage curves of CNFs grown on silicon and on niobium titanium nitride, respectively.

FIG. 4A shows a nano-electro-mechanical switch (NEMS.

FIG. 4B shows a NEMS that is closed (on).

FIG. 5 shows a current-voltage curve of a nano-electro-mechanical switch (NEMS), in accordance with an embodiment of the present disclosure.

FIG. 6 shows a current-voltage curve of a NEMS.

FIG. 7 shows current-voltage curves of a NEMS.

FIG. 8 shows a leakage-current-voltage curve of a NEMS.

### DETAILED DESCRIPTION

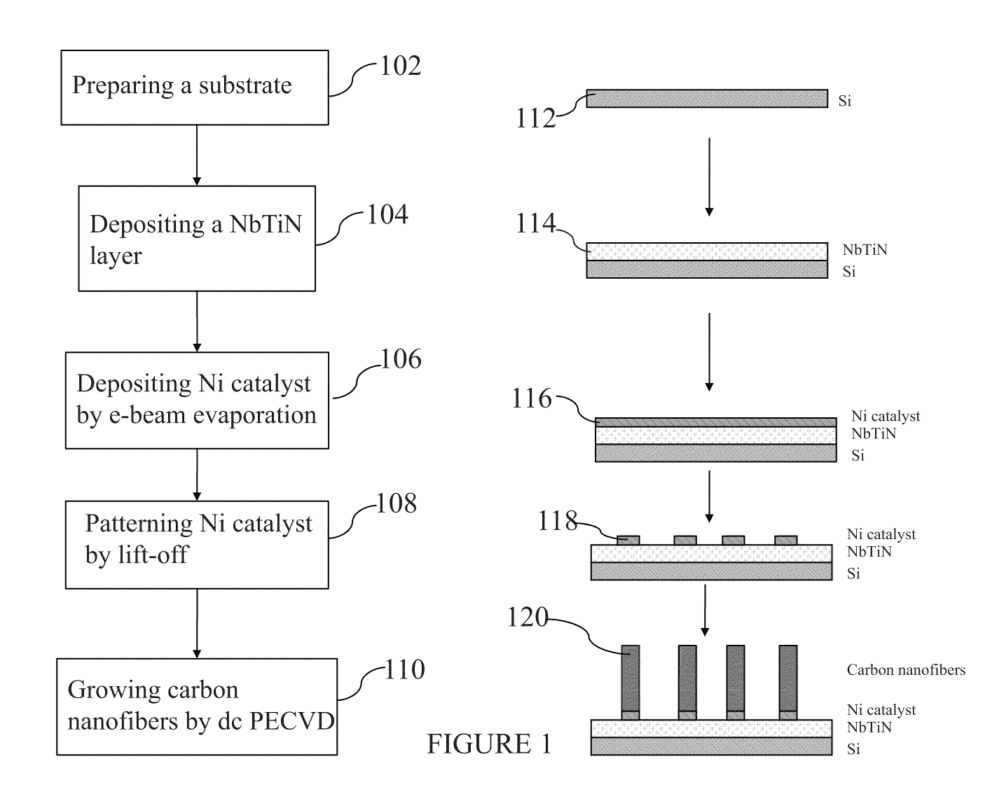

FIG. 1 depicts a process flow for fabricating one or more three-dimensional (3D), or vertical, sidewall-conductive carbon nanofibers (CNFs), in accordance with an embodiment of the present disclosure. According to this embodiment, the CNF fabrication starts with preparing (102) a substrate (112). A person having ordinary skill in the art would understand that the preparation of the substrate (112) may include cleaning the substrate and other treatments, depending on substrate properties. By way of example and not of limitation, the substrate (112) can be <100> silicon with resistivity of 1˜5 mΩ-cm. A person having ordinary skill in the art knows that other materials may be used in place of silicon.

Next, a niobium titanium nitride (NbTiN) layer (114) is deposited (104) on the substrate (112), e.g., through magnetron sputtering. Other deposition processes may be used to deposit the NbTiN layer: for example, e-beam evaporation. By way of example and not of limitation, the NbTiN layer (114) is chemically compatible with CNF synthesis, refractory, around 200 nm thick, and has resistivity of around 113 μΩ-cm. The NbTiN layer withstands the high growth temperatures in the PECVD growth environment, the corrosive growth environment (e.g. with the use of ammonia at elevated temperatures), and it also serves as a substrate which maintains catalytic activity of the Ni-catalyst for the CNF synthesis.

Next, in accordance with the embodiment shown in FIG. 1, a nickel (Ni) catalyst layer (116) is deposited (106) on the NbTiN-coated substrate, e.g., by e-beam evaporation. A person ordinarily skilled in the art could also use other deposition methods, like sputtering. Then, the Ni catalyst layer (116) is patterned (108) to form Ni catalysts islands (118), e.g., through a liftoff process. A person having ordinary skill in the art understands that some steps of the liftoff process, such as spin-coating photoresist, lithography, etc. can occur before the deposition of the Ni catalyst layer (116). Other patterning approaches may be used to form the Ni catalysts islands (118). Other catalyst materials may be used: Cobalt (Co), Iron (Fe), Fe on Aluminium (Fe/Al), Co on Titanium (Co/Ti), Scandium (Sc), Copper (Cu), etc.

With continued reference to FIG. 1, 3D CNFs (120) are then grown (110) on the Ni catalyst islands (118), e.g., by a direct current plasma-enhanced chemical vapor deposition (dc PECVD) process. By way of example and not of limitation, the parameters of the dc PECVD process are C₂H₂: NH₃=1:4, total pressure=5 Torr, temperature=700° C. and plasma power=200 W. Depending on process conditions, the plasma power ranges from 150 W to 240 W. Other growing processes may be used: for example, electric-field assisted CVD, laser-assisted CVD, and arc-discharge CVD. In a C₂H₂-rich or carbon-rich gas environment, the substrate could be coated with amorphous silicon. In an ammonia (NH₃)-rich gas environment, bodies of growing CNFs may be etched due to the reducing effect arising from the excess hydrogen. Therefore, for a dc PECVD process, the gas ratio is properly determined.

The properties of 3D CNFs depend on the choice of substrate. According to an embodiment of the present disclosure, 3D CNFs growing on a NbTiN-coated substrate have electrically conductive sidewalls. According to another embodiment of the present disclosure, 3D CNFs growing on a silicon substrate have a conformal dielectric coating on the sidewalls. Thus, by controlling the substrate, one may control the electrical property of the resulting 3D CNFs.

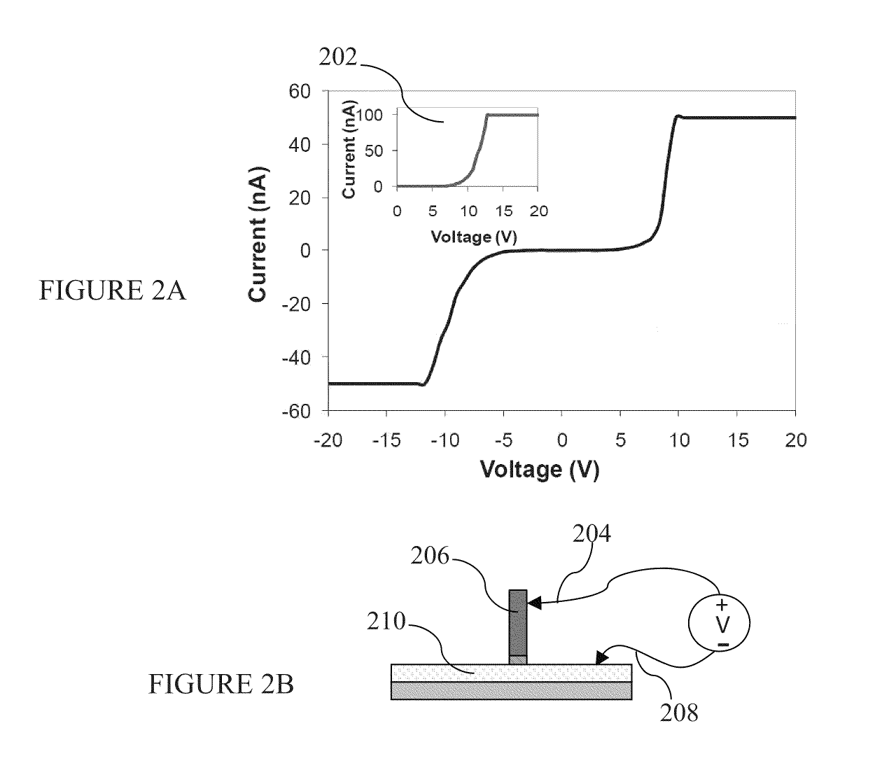

FIG. 2A depicts a current-voltage (I-V) curve of a 3D sidewall-conductive CNF, in accordance to an embodiment of the present disclosure. In this embodiment, the I-V curve of FIG. 2A is measured with a nanoprobe apparatus where the nanoprobe was made from the metal tungsten (W). With reference to FIG. 2B, in accordance with a further embodiment of the present disclosure, the positive terminal nanoprobe (204) is mechanically manipulated to be in physical contact with an individual CNF (206) grown on NbTiN. The negative terminal probe (208) is connected to the substrate (210).

With continued reference to FIG. 2A, the CNF is electrically conductive. Yet, no measureable current could be detected until around 6 V. When the voltage is higher than 6 V, current increases sharply until reaching the compliance (around 50 nA) at around 9.5 V. The work function φ for tungsten (W) φ_{W}˜4.5 eV<φ_{CNF}˜5.0 eV [Reference 1], and suggests a Schottky barrier may arise at this interface, and also possibly at the CNF-to-substrate interface; φ_{NbTiN}˜3.92 eV and like most transition metal nitrides with low φ [Reference 2], it is likely φ_{NbTiN}<φ_{CNF}. A sub-gap region with suppressed conductance at low biases was seen in both polarities, and may have arisen from a native oxide on the W probes; if a small semiconducting junction (e.g. Schottky) also exists, an asymmetry in the I-V characteristic would arise, as observed. In addition, current conduction at lower voltages may be hindered by native oxide, a tunnel barrier, on the probe tip. According to the inset (202) of FIG. 2A, current up to around 100 nA is measured. The current likely propagates via the CNF surfaces or sidewalls, rather than the CNF body.

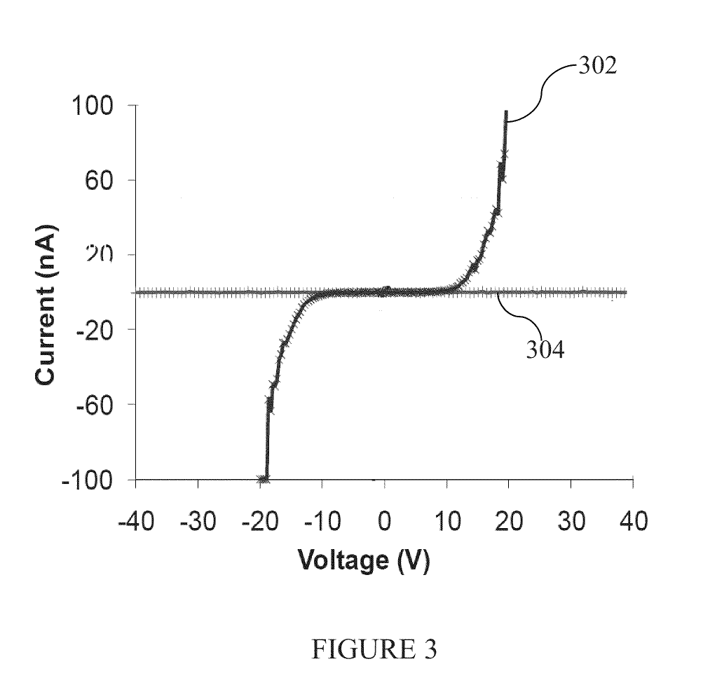

FIG. 3 shows I-V curves of CNFs grown on Si and on NbTiN, respectively, in accordance with several embodiments of the present disclosure. The curve (302) is the I-V curve of a CNF grown on NbTiN, according to an embodiment of the present disclosure. As a control and comparison, the curve (304) is the I-V curve of a CNF grown on Si (with no NbTiN coating), according to an example of the present disclosure. Like FIG. 2A, the curve (302) shows that the CNF grown on NbTiN is electrically conductive. But no measurable current is detected for the CNF grown on Si (without NbTiN coating), as indicated by the curve (304). This shows that the CNF grown on Si (without NbTiN coating) is not electrically conductive. This inability to conduct current could arise from a dielectric coating on sidewalls of CNFs grown on Si. The dielectric coating may originate from directional ion bombardments during the dc PECVD. Directional ion bombardments are likely to sputter Si from the substrate; Si could then deposit on the CNF sidewalls. Si on the CNF sidewalls then reacts with nitrogen, which is abundant in the reaction gas compositions (around 80% is NH₃). Si and N form SiNx on the CNF sidewalls. The presence of SiN_{X} sheaths on CNF sidewalls has been confirmed by Melechko et al. through chemical analysis using energy-dispersive-X-ray (EDX) analysis [Reference 3]. SiN_{X} forming on the substrate is likely to be removed by directional ion bombardments on the substrate.

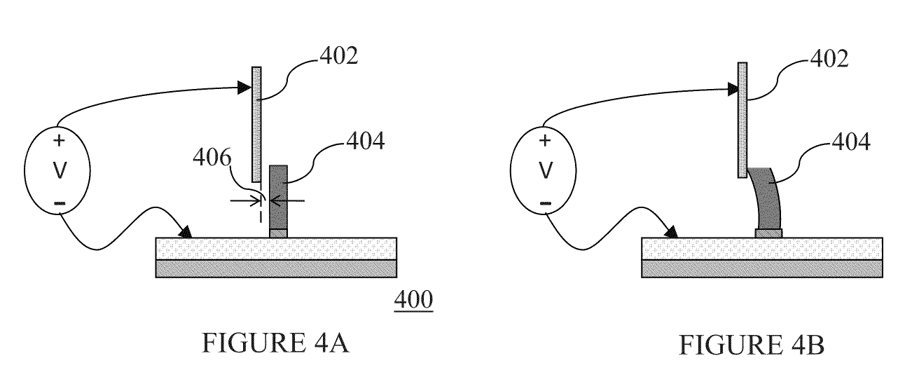

FIG. 4A shows a nano-electro-mechanical switch (NEMS) (400), according to an embodiment of the present disclosure. According to this embodiment, the NEMS (400) comprises a sidewall-conductive CNF (404) and a nanoprobe (402). Other embodiments of the present disclosure may use a second sidewall-conductive CNF, a metal rod, or other conducting materials in place of the nanoprobe (402). According to the embodiment of the present disclosure shown in FIG. 4A, the nanoprobe (402) is placed at a gap distance, g, (406) from the sidewall-conductive CNF (404). By way of example and not of limitation, the gap distance (406) can be a few hundred nanometers. The NEMS (400) in FIG. 4A is in an open (off) condition, while the NEMS in FIG. 4B is in a closed (on) condition.

According to an embodiment of the present disclosure, the electrostatic force per unit length of a sidewall-conductive CNF, F_{Elec}, increases in proportion to V², where V is the voltage applied between the nanoprobe (402) and the sidewall-conductive CNF (404). In addition, the elastostatic force per unit length of the CNF (404), F_{Elasto}, increases as the product of E and I, where E is the elastic modulus of the CNF, and I the moment of inertia of the CNF.

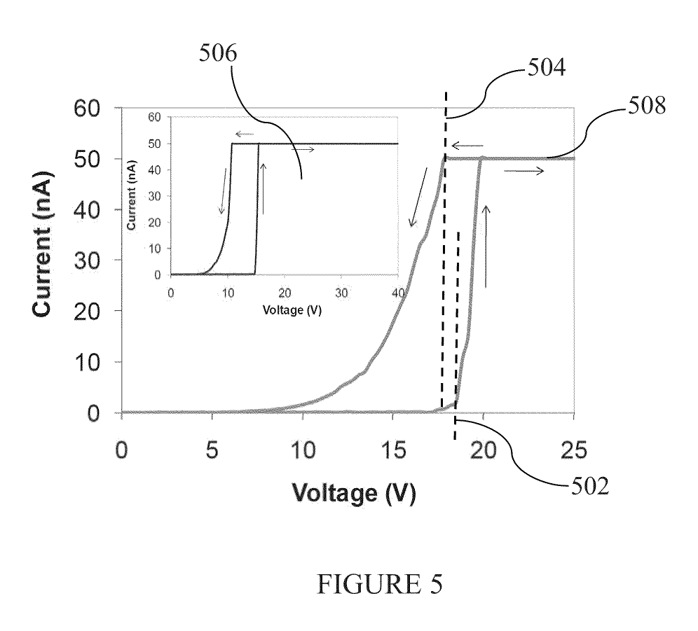

FIG. 5 shows an I-V curve (508) of the NEMS (400) of FIG. 4A, in accordance with an embodiment of the present disclosure. According to this embodiment, the NEMS (400) is initially open and, therefore, no current flows through the NEMS (400). As the voltage increases, F_{Elec} increases. When F_{Elec} is greater than F_{Elasto}, the sidewall-conductive CNF (404) of FIG. 4A starts to bend toward the nanoprobe (402). This change is reflected by the I-V curve (508) in FIG. 5, as current rises fast at Vₚᵢ (502). According to the I-V curve (508) in FIG. 5, Vₚᵢ (502) is around 18 V. As the voltage further increases, the current through the NEMS (400) reaches the compliance (around 50 nA). The NEMS (400) is in a closed (on) condition, as shown in FIG. 4B.

With continued reference to FIG. 5, the turn-off of the NEMS (400) in FIG. 4A occurs at around 16 V (502), in accordance with an embodiment of the present disclosure. The turn-off voltage is dominated by large CNF-to-nanoprobe contact resistance. This is because the sidewall-conductive CNF (404) of the NEMS (400) contacts the nanoprobe (402), as shown in FIG. 4B.

The inset (506) of FIG. 5 shows an I-V curve of a NEMS in accordance with another embodiment of the present disclosure. The I-V curve of the inset (506) also shows similar switching transitions as FIG. 5. The embodiment shown in the inset (506) has a turn-on voltage of around 14 V and a turn-off voltage of 10 V.

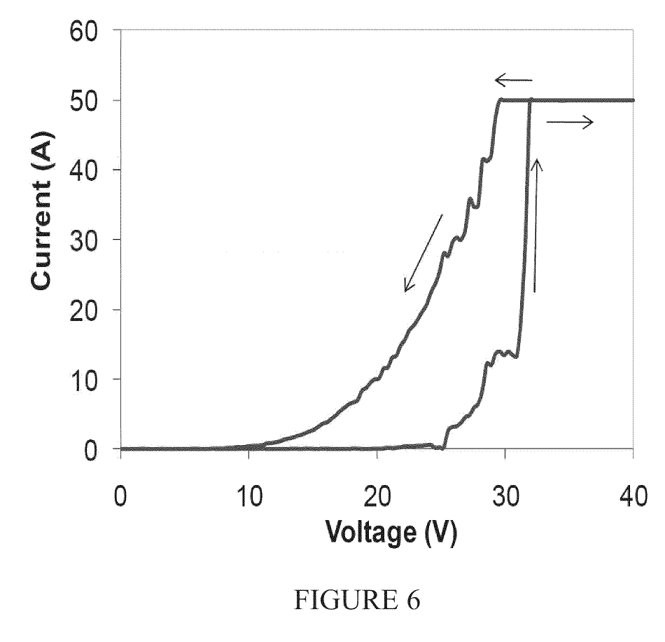

FIG. 6 shows an I-V curve of another NEMS, in accordance with another embodiment of the present disclosure. In this embodiment, the sidewall-conductive CNF of the NEMS is around 2.8 μm long, around 60 nm in diameter, and has a gap distance of 160 nm to the nanoprobe. Vₚᵢ for this embodiment is around 26 V.

All the I-V curves shown in FIGS. 5 and 6 show hysteresis. Hysteresis may arise from the CNF sticking to the nanoprobe. The stiction occurs even when V=0. The stiction at zero volts is evidence that the van der Waals force, F_{vdw} is greater than the elastostatic force, F_{Elasto}, which is responsible for causing the CNF to retract to the ‘open’ position as shown in FIG. 4A. The stiction at zero volts and hysteresis suggest that the NEMS may be useful for nonvolatile memory applications since zero power is consumed in the switched state.

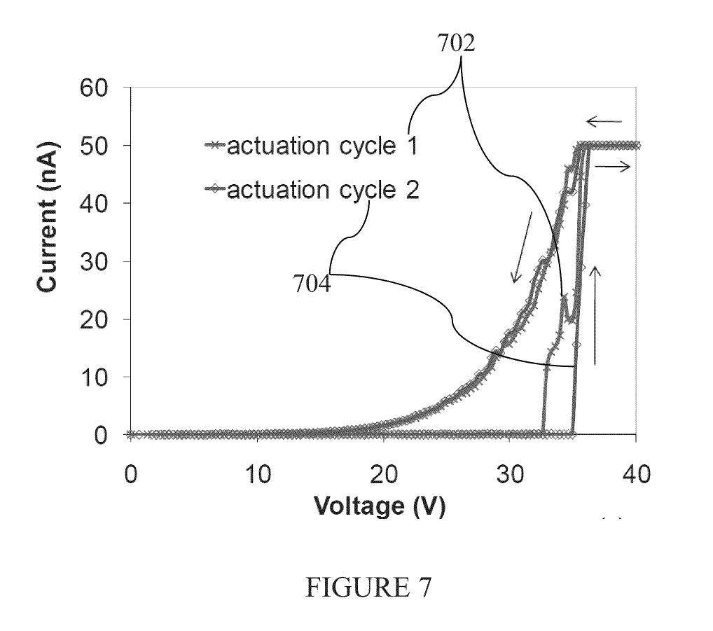

FIG. 7 shows I-V curves (702, 704) of a NEMS in accordance with an embodiment of the present disclosure. In this embodiment, the NEMS of FIG. 7 uses the same CNF and nanoprobe as the NEMS in FIG. 6, but a larger gap distance. According to this embodiment, the gap distance is 220 nm. The two I-V curves (702, 704) shown in FIG. 7 represent two switching cycles (a switch cycle is turning on the NEMS, and then turning it off). From the I-V curve of the first switching cycle (702), Vₚᵢ is around 32 V, which is greater than that of the NEMS of FIG. 6. This is because Vₚᵢ is in proportion to the 3/2 power of the gap distance, g (Vₚᵢ∝g^{3/2}), and because the gap distance in this embodiment is 220 nm, larger than that of the NEMS of FIG. 6. From the I-V curve of the first switching cycle (704), Vₚᵢ is around 35 V. The I-V curves (702, 704) of both switching cycles have similar, almost identical turning-off voltages.

The I-V curves shown in FIGS. 5-7 all show abrupt or near vertical switching transitions. The fast switching characteristics make the NEMS useful in ultra-fast switching applications (e.g., GHz-range applications). The NEMS is also useful for high frequency electronics.

According to another embodiment of the present disclosure, a NEMS can be configured not to switch on or off if it uses the same CNF and nanoprobe as that of FIG. 6, but has a gap distance greater than 400 nm,

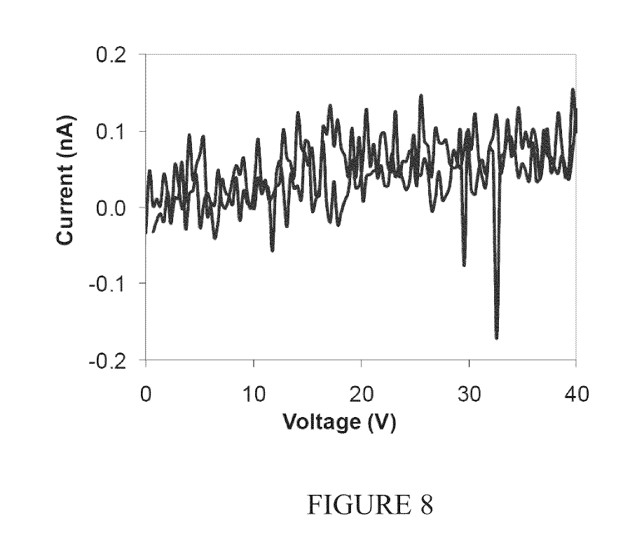

FIG. 8 shows the leakage current of the NEMS shown in FIG. 7. According to this embodiment of the present disclosure, the leakage current is less than 150 pA up to 40 V.

The examples set forth above are provided to give those of ordinary skill in the art a complete disclosure and description of how to make and use the embodiments of the nano-electro-micro switches using three-dimensional sidewall-conductive carbon nanofibers and method for making the same of the disclosure, and are not intended to limit the scope of what the inventors regard as their disclosure. Modifications of the above-described modes for carrying out the disclosure may be used by persons of skill in the art, and are intended to be within the scope of the following claims. All patents and publications mentioned in the specification may be indicative of the levels of skill of those skilled in the art to which the disclosure pertains. All references cited in this disclosure are incorporated by reference to the same extent as if each reference had been incorporated by reference in its entirety individually.

It is to be understood that the disclosure is not limited to particular methods or systems, which can, of course, vary. It is also to be understood that the terminology used herein is for the purpose of describing particular embodiments only, and is not intended to be limiting. As used in this specification and the appended claims, the singular forms “a,” “an,” and “the” include plural referents unless the content clearly dictates otherwise. The term “plurality” includes two or more referents unless the content clearly dictates otherwise. Unless defined otherwise, all technical and scientific terms used herein have the same meaning as commonly understood by one of ordinary skill in the art to which the disclosure pertains.

A number of embodiments of the disclosure have been described. Nevertheless, it will be understood that various modifications may be made without departing from the spirit and scope of the present disclosure. Accordingly, other embodiments are within the scope of the following claims.

### LIST OF REFERENCES

[1] S. Ahmed, S. Das, M. K. Mitra, and K. K. Chattopadhyay Appl. Surf. Sci. 254, 610 (2007).

[2] Y. Saito, S. Kawata, H. Nakane, and H. Adachi Appl Surf. Sci 146, 177 (1999).

[3] A. V. Melechko, T. E. McKnight, D. K. Hensley, M. A. Guillom, A. Y. Borisevich, V. I. Merkulov, D. H. Lowndes, and M. L. Simpson, Nanotech. 14, 1029 (2003).

We claim:

1. A method for fabricating sidewall-conductive carbon nanofibers (CNFs), comprising:
depositing a niobium titanium nitride (NbTiN) layer on a substrate;
depositing a catalyst layer on the NbTiN layer;
patterning the catalyst layer; and
growing at least one sidewall-conductive CNF on the patterned catalyst layer.

2. The method according to claim 1, wherein the at least one sidewall-conductive CNF is perpendicular to the substrate.

3. The method according to claim 1, wherein the substrate comprises a silicon wafer.

4. The method according to claim 1, wherein the depositing of the NbTiN layer comprises performing magnetron sputtering.

5. The method according to claim 1, wherein the catalyst layer comprises a nickel (Ni) catalyst layer.

6. The method according to claim 5, wherein the deposition of the Ni catalyst layer comprises e-beam evaporating of Ni.

7. The method according to claim 5, wherein the patterning of the Ni catalyst layer comprises performing a liftoff process.

8. The method according to claim 1, wherein the growing of the at least one sidewall-conductive CNF comprises performing growing through direct current plasma enhanced chemical vapor deposition (dc PECVD).

9. The method according to claim 8, wherein gases used in the dc PECVD comprise C₂H₂ and NH₃, the ratio of C₂H₂:NH₃ being around 1:4.

10. A nano-electro-mechanical switch, comprising:
a first electrical conductor; and
a second electrical conductor located at a distance to the first electrical conductor, wherein
at least one of the first electrical conductor and the second electrical conductor comprises a sidewall-conductive carbon nanofiber (CNF); and
the first and the second electrical conductors are adapted to form a current conducting path when a voltage higher than a turn-on voltage is applied between the first and the second electrical conductors.

11. The nano-electro-mechanical switch according to claim 10, wherein the at least one sidewall-conductive CNF is perpendicular to a substrate.

12. The nano-electro-mechanical switch according to claim 11, wherein the substrate comprises a layer of niobium titanium nitride (NbTiN).

13. The nano-electro-mechanical switch according to claim 10, wherein the first and the second electrical conductors are adapted to contact each other when a voltage higher than a turn-on voltage is applied and to separate at a distance between each other when a voltage lower than a turn-off voltage is applied.

14. The nano-electro-mechanical switch according to claim 13, wherein the turn-on voltage is different from the turn-off voltage.

15. The nano-electro-mechanical switch according to claim 10, wherein the first and the second electrical conductors are adapted to be actuated through an electrostatic approach.

16. The nano-electro-mechanical switch according to claim 10, wherein the first and the second electrical conductors are adapted to remain in contact with each other when a voltage between the first and the second electrical conductors changes from higher than a turn-on voltage to zero.

17. A carbon nanofiber, comprising electrically conductive sidewalls.

18. The carbon nanofiber according to claim 17, further comprising
a patterned Ni catalyst layer around which the electrically conductive sidewalls are located; and
a NbTiN layer on which the Ni catalyst layer is located.

19. A method for fabricating three-dimensional carbon nanofibers (CNFs) with conformal dielectric sidewall coating, comprising:
depositing a nickel (Ni) catalyst layer on a silicon (Si) layer;
patterning the Ni catalyst layer; and
growing at least one three-dimensional CNF with conformal dielectric sidewall coating on the patterned Ni catalyst layer through direct current plasma enhanced chemical vapor deposition (dc PECVD).

20. The method according to claim 19, wherein
gases used in the dc PECVD comprise C₂H₂ and NH₃, the ratio of C₂H₂:NH₃ being around 1:4;
pressure used in the dc PECVD is 5 Torr during CNF growth;
temperature used in the dc PECVD is around 700° C.; and
power used in the dc PECVD is 150 W to 240 W.
